(19) United States
(12) Patent Application Publication
(10) Pub. No.: US 2026/0333717 A1
(43) Pub. Date: Oct. 22, 2026

(54) RESISTOR STRUCTURE HAVING CAVITIES FOR INCREASED RESISTOR PERFORMANCE

(71) Applicant: Taiwan Semiconductor Manufacturing Company, Ltd., Hsinchu (TW)

(72) Inventors: Chun-Heng Chen, Hsinchu City (TW); Hsi-Jung Wu, Kaohsiung City (TW); Jiun-Jie Huang, Kaohsiung City (TW); Ru-Shang Hsiao, Jhubei City (TW); Yu-Wei Liang, Kaohsiung City (TW); Yu-Chun Chang, New Taipei City (TW)

(21) Appl. No.: 19/721,599

(22) Filed: Jun. 26, 2026

Related U.S. Application Data
(62) Division of application No. 18/312,726, filed on May 5, 2023.

(51) Int. Cl. H10D 1/47; H01C 7/00

(52) U.S. Cl. CPC H10D 1/47; H01C 7/006; H10D 1/474

(57) ABSTRACT

Various embodiments of the present disclosure are directed towards an integrated chip including a resistor structure overlying a semiconductor substrate. A dielectric structure overlies the semiconductor substrate. The resistor structure is disposed within the dielectric structure. The resistor structure includes a thin film resistor (TFR) layer and a first capping structure disposed on the TFR layer. A first cavity is disposed within the dielectric structure and abuts a first sidewall of the first capping structure.

### REFERENCE TO RELATED APPLICATION

This Application is a Divisional of U.S. application Ser. No. 18/312,726, filed on May 5, 2023, the contents of which are hereby incorporated by reference in their entirety.

### BACKGROUND

Modern integrated chips use a wide range of devices to achieve varying functionalities. In general, integrated chips comprise active devices and passive devices. Active devices include transistors (e.g., metal-oxide-semiconductor field-effect transistor (MOSFETs)), while passive devices include inductors, capacitors, and resistors. Resistors are widely used in many applications such as resistor-capacitor (RC) circuits, power drivers, power amplifiers, radio frequency (RF) applications, etc.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a cross-sectional view of some embodiments of an integrated chip including a plurality of cavities laterally adjacent to capping structures of a resistor structure.

FIG. 2 illustrates a top view of some embodiments of the integrated chip of FIG. 1 taken along line A-A′.

FIGS. 3A and 3B illustrate cross-sectional views of some alternative embodiments of an integrated chip including a plurality of cavities laterally adjacent to capping structures of a resistor structure.

FIGS. 4A and 4B illustrate cross-sectional views of some other embodiments of the integrated chip of FIG. 3A.

FIGS. 5A and 5B illustrate cross-sectional views of some other embodiments of the integrated chip of FIG. 3A.

FIGS. 6A-6D illustrate cross-sectional views of some other embodiments of the integrated chip of FIG. 3A.

FIG. 7A illustrates a cross-sectional view of some other embodiments of the integrated chip of FIG. 3A.

FIGS. 7B and 7C illustrate cross-sectional views of some other embodiments of an area of the integrated chip of FIG. 7A.

FIG. 8A illustrates a cross-sectional view of some other embodiments of the integrated chip of FIG. 3A.

FIGS. 8B and 8C illustrate cross-sectional views of some other embodiments of an area of the integrated chip of FIG. 8A.

FIG. 9A illustrates a cross-sectional view of some other embodiments of the integrated chip of FIG. 3A.

FIGS. 9B and 9C illustrate cross-sectional views of some other embodiments of an area of the integrated chip of FIG. 9A.

FIG. 10 illustrates a cross-sectional view of some embodiments of an integrated chip having a resistor structure disposed within an interconnect structure.

FIGS. 11-16 illustrate cross-sectional views of some embodiments of a method for forming an integrated chip including a resistor structure comprising cavities adjacent to capping structures.

FIGS. 17-23 illustrate cross-sectional views of some other embodiments of a method for forming an integrated chip including a resistor structure comprising cavities adjacent to capping structures.

FIGS. 24-29 illustrate cross-sectional views of some embodiments of a method for forming an integrated chip including a resistor structure comprising cavities adjacent to capping structures.

FIGS. 30-33 illustrate cross-sectional views of some other embodiments of a method for forming an integrated chip including a resistor structure comprising cavities adjacent to capping structures.

FIG. 34 illustrates a flowchart of some embodiments of a method for forming an integrated chip including a resistor structure comprising cavities adjacent to capping structures.

### DETAILED DESCRIPTION

The present disclosure provides many different embodiments, or examples, for implementing different features of this disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Some integrated chips have passive devices disposed over/within a substrate. The passive devices may, for example, include inductors, resistors, capacitors, diodes, etc. One type of resistor used in an integrated chip is a thin film resistor (TFR). The TFR comprises a TFR layer (e.g., a resistive layer) that extends between two conductive capping structures. A dielectric structure overlies and laterally encloses the TFR layer and the two conductive capping structures. Typically, the TFR layer comprises a first material (e.g., silicon chromium (SiCr)) having a first coefficient of thermal expansion (CTE) and the conductive capping structures comprise a second material (e.g., titanium nitride, tantalum nitride, titanium tungsten, etc.) having a second CTE different from the first CTE.

During fabrication and/or operation of TFRs, the TFR layer and the conductive capping structures may be exposed to high temperatures. For example, one or more tests (e.g., a higher temperature operating life (HTOL) test, a high temperature storage life (HTSL) test, etc.) may be performed on a TFR to determine a quality and/or reliability of the TFR. During the one or more tests, the TFR is exposed to high temperatures (e.g., 175° Celsius or higher). Due to a mismatch between the first and second CTEs of the TFR layer and the conductive capping structures, the TFR layer may be exposed to high stress (e.g., high compressive stress, high tensile stress, etc.) while under the high temperatures. The high stress may damage the TFR layer, thereby reducing a safe operating area (e.g., a voltage and/or current range that may be applied to the TFR without damage or degradation of performance) of the TFR and reducing a reliability of the TFR. For example, the high stress may cause sheet resistance variation across different regions of the TFR layer (e.g., regions of the TFR layer near the conductive capping structures). As a result, an overall performance of the TFR is reduced and the TFR may not meet design specifications (e.g., due to the variation of sheet resistance across the TFR layer).

Accordingly, the present disclosure is directed towards an integrated chip having a resistor structure (e.g., a TFR structure) comprising capping structures disposed on a TFR layer and one or more cavities abutting the capping structures. The TFR layer and the capping structures are disposed within a dielectric structure. The TFR layer has a first coefficient of thermal expansion (CTE) and the capping structures have a second coefficient of CTE different from (e.g., greater than) the second CTE. The one or more cavities are disposed within the dielectric structure and are adjacent to a corresponding sidewall of the capping structures. The one or more cavities have a third CTE greater than the second CTE. Because the resistor structure comprises the one or more cavities with the third CTE greater than the second CTE, high stress induced on the TFR layer by the capping structures under high temperatures (e.g., 175° Celsius or higher) is reduced. As such, sheet resistance across the TFR layer is more uniform, a reliability of the resistor structure is increased, and a safe operating area of the resistor layer may be maintained or increased. Accordingly, an overall performance of the the resistor structure is increased.

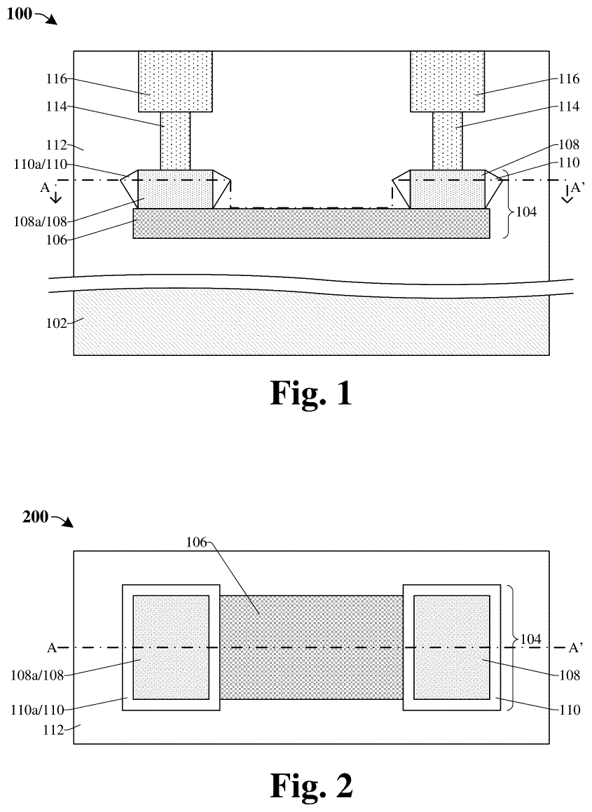

FIG. 1 illustrates a cross-sectional view 100 of some embodiments of an integrated chip including a plurality of cavities 110 laterally adjacent to capping structures 108 of a resistor structure 104.

The integrated chip comprises a dielectric structure 112 overlying a semiconductor substrate 102. The resistor structure 104 is disposed within the dielectric structure 112. A plurality of conductive vias 114 are disposed within the dielectric structure 112 and overlie the resistor structure 104. A plurality of conductive wires 116 are disposed within the dielectric structure 112 and overlie the conductive vias 114. The conductive vias and wires 114, 116 are electrically coupled to the resistor structure 104.

The resistor structure 104 comprises a thin film resistor (TFR) layer 106 and a pair of capping structures 108 disposed on opposing sides of the TFR layer 106. In various embodiments, the capping structures 108 directly contact a top surface of the TFR layer 106. The TFR layer 106 comprises a first material (e.g., silicon chromium (SiCr)) having a first coefficient of thermal expansion (CTE). Further, the capping structures 108 comprise a second material (e.g., titanium nitride) having a second CTE different from (e.g., greater than) the first CTE. In some embodiments, the capping structures 108 are conductive and are configured to electrically couple the TFR layer 106 to the plurality of conductive vias 114. The resistor structure 104 is configured to resist (e.g., reduce) current flow between the capping structures 108. In some embodiments, the resistor structure 104 may, for example, be used in resistor-capacitor (RC) circuits, power drivers, power amplifiers, RF applications, analog-to-digital converters (ADCs), digital-to-analog converters (DACs), other suitable electronic devices, or any combination of the foregoing.

A plurality of cavities 110 are disposed within the dielectric structure 112 and abut a corresponding capping structure 108. In some embodiments, the cavities 110 laterally wrap around a corresponding one of the capping structures 108. For example, the plurality of cavities 110 comprise a first cavity 110a and the capping structures 108 comprise a first capping structure 108a. In various embodiments, the first cavity 110a continuously wraps around an outer perimeter of the first capping structure 108a. The cavities 110 may be defined by one or more surfaces of the dielectric structure 112 and/or one or more surfaces of the capping structures 108. In yet further embodiments, the cavities 110 are further defined by one or more surfaces of the TFR layer 106. The cavities 110 have a third CTE different from the first CTE and the second CTE. In some embodiments, the cavities 110 comprise air and may be configured as or referred to as air-gaps. In various embodiments, the third CTE is greater than the first CTE and the second CTE.

Because the plurality of cavities 110 are adjacent to a corresponding capping structure 108, stress on the TFR layer 106 (e.g., induced by the capping structures 108) under high temperatures is reduced. For example, during fabrication, operation, and/or testing (e.g., a higher temperature operating life (HTOL) test, a high temperature storage life (HTSL) test, etc.) of the resistor structure 104, the resistor structure 104 is exposed to high temperatures (e.g., 175° Celsius or higher). As a result of the second CTE of the capping structures 108 being greater than the first CTE of the TFR layer 106, the capping structures 108 are likely to expand more than the TFR layer 106 under the high temperatures. By virtue of the third CTE of the cavities 110 being greater than the second CTE of the capping structures 108, the cavities 110 may expand more than the capping structures 108 under the high temperatures thereby balancing and/or mitigating expansion of the capping structures 108. This, in part, balances and/or mitigates stress (e.g., compressive stress, tensile stress, etc.) applied to the TFR layer 106 by the capping structures 108, thereby mitigating adverse effects on the TFR layer 106. For example, the balanced and/or mitigated stress on the TFR layer 106 may increase sheet resistance uniformity across the TFR layer 106, increase a reliability of the TFR layer 106, and/or increase a safe operating area of the TFR layer 106. Accordingly, an overall performance of the resistor structure 104 is increased.

FIG. 2 illustrates a top view 200 of some embodiments of the cross-sectional view 100 of FIG. 1 taken along line A-A′.

As illustrated in FIG. 2, in some embodiments, the cavities 110 laterally enclose a corresponding capping structure 108. For example, the first cavity 110a continuously extends around an outer perimeter of the first capping structure 108a.

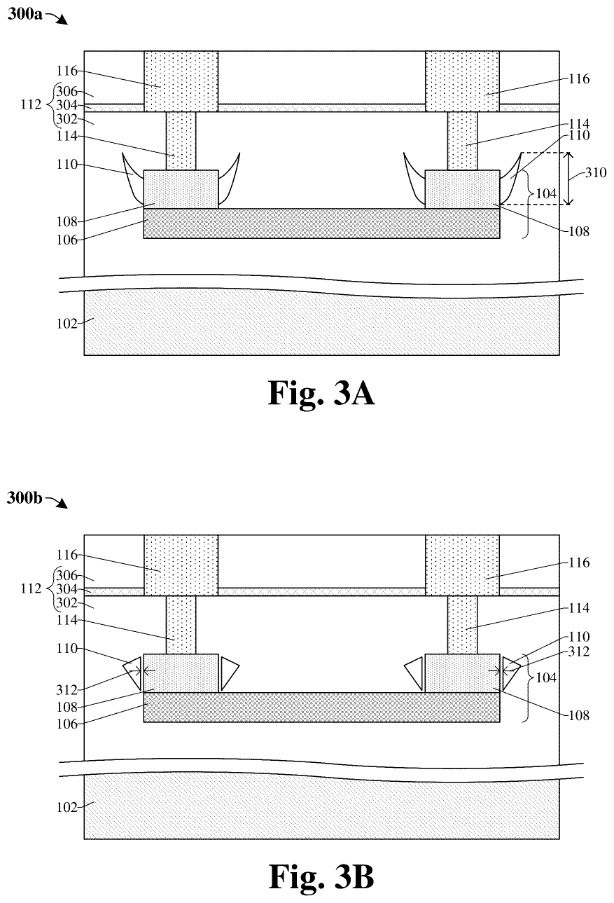

FIG. 3A illustrates a cross-sectional view 300a of some other embodiments of an integrated chip including a plurality of cavities 110 laterally adjacent to capping structures 108 of a resistor structure 104.

The integrated chip comprises a dielectric structure 112 overlying a semiconductor substrate 102. The semiconductor substrate 102 may, for example, be or comprise a semiconductor substrate material (e.g., silicon, silicon germanium, etc.), a bulk silicon substrate (e.g., bulk silicon), a semiconductor-on-insulator (SOI) substrate, one or more epitaxial layers, or another suitable substrate material. In some embodiments, the dielectric structure 112 comprises a first dielectric layer 302, a first etch stop layer 304, and a second dielectric layer 306. The first and second dielectric layers 302, 306 may, for example, be or comprise silicon dioxide, a low-k dielectric material such as undoped silica glass (USG) and/or carbon-doped silicon dioxide, some other suitable dielectric, or any combination of the foregoing. As used herein, a low-k dielectric material is a dielectric material with a dielectric constant less than 3.9. The first etch stop layer 304 may, for example, be or comprise silicon nitride, silicon carbide, or the like. A plurality of conductive vias 114 are disposed within the first dielectric layer 302. A plurality of conductive wires 116 are disposed within the second dielectric layer 306 and overlie the conductive vias 114. The conductive vias and wires 114, 116 may, for example, be or comprise copper, aluminum, tungsten, titanium nitride, tantalum nitride, ruthenium, another conductive material, or any combination of the foregoing.

The resistor structure 104 is disposed within the first dielectric layer 302. The resistor structure 104 comprises a TFR layer 106 and a pair of capping structures 108 disposed on opposing sides of the TFR layer 106. The TFR layer 106 comprises a first material having a first CTE. In some embodiments, the first material is or comprises silicon chromium, silicon chromium nickel, silicon chromium oxide, silicon chromium nitride, or the like. In further embodiments, the first CTE may be within a range of about 3.5*10⁻⁶/K to 4.5*10⁻⁶/K, about 4*10⁻⁶/K or some other suitable value. In yet further embodiments, the TFR layer 106 has a thickness within a range of about 5 to 200 angstroms, less than about 200 angstroms, or some other value. The capping structures 108 comprises a second material having a second CTE. In some embodiments, the second material is or comprises titanium nitride, titanium tungsten, tantalum nitride, tantalum tungsten, or the like. In further embodiments, the second CTE may be within a range of about 22.5*10⁻⁶/K to 24.5*10⁻⁶/K, about 23.4*10⁻⁶/K, or some other suitable value. In yet further embodiments, the capping structures 108 have a thickness within a range of about 50 to 1,000 angstroms or some other suitable value. In some embodiments, the first CTE is less than the second CTE. In various embodiment, the thickness of the TFR layer 106 is less than the thickness of the capping structures 108.

A plurality of cavities 110 are disposed within the first dielectric layer 302 and are respectively adjacent to a corresponding capping structure 108. In some embodiments, the cavities 110 are defined by one or more surfaces of the capping structures 108 (e.g., one or more sidewalls of the capping structures 108) and/or one or more surface of the first dielectric layer 302. The cavities 110 have a third CTE different from the first CTE and the second CTE. For example, the third CTE is greater than the first CTE and the second CTE. In some embodiments, the cavities comprise a third material (e.g., air) having the third CTE. In various embodiments, the third CTE may be within a range of about 1,500*10⁻⁶/K to 3,000*10⁻⁶/K, about 2,000*10⁻⁶/K, or some other suitable value. In further embodiments, a height 310 of the cavities 110 is greater than the thickness of the TFR layer 106 and/or is greater than the thickness of the capping structures 108. In yet further embodiments, the height 310 of the cavities 110 is less than the thickness of the capping structures 108 (not shown). Further, a bottom of the cavities 110 may be disposed above a top surface of the TFR layer 106 and/or a top of the cavities 110 may be disposed above a top surface of the capping structures 108. By virtue of a shape, a location relative to the capping structures 108 and/or TFR layer 106, and/or the third CTE of the cavities 110, stress (e.g., tensile stress, compression stress) applied to the TFR layer 106 under high temperatures is decreased. This, in part, may increase resistance uniformity across the TFR layer 106, increase a reliability of the TFR layer 106 (e.g., after being exposed to high temperatures such as after an HTOL test, an HTSL test, etc.), and/or increase a safe operating area of the TFR layer 106.

Further, the first dielectric layer 302 comprises a fourth material (e.g., silicon dioxide) having a fourth CTE less than the second CTE and/or the third CTE. In further embodiments, the fourth CTE is greater than the first CTE. The fourth CTE may, for example, be about 6*10⁻⁶/K or some other suitable value.

FIG. 3B illustrates a cross-sectional view 300b corresponding to some other embodiments of the integrated chip of FIG. 3A, in which the cavities 110 are laterally separated from sidewalls of the capping structures 108 by a lateral distance 312. In such embodiments, the cavities 110 are entirely defined by one or more surfaces of the first dielectric layer 302. In some embodiments, the lateral distance 312 is greater than zero. In further embodiments, a height of the cavities 110 is less than a thickness of the capping structures 108.

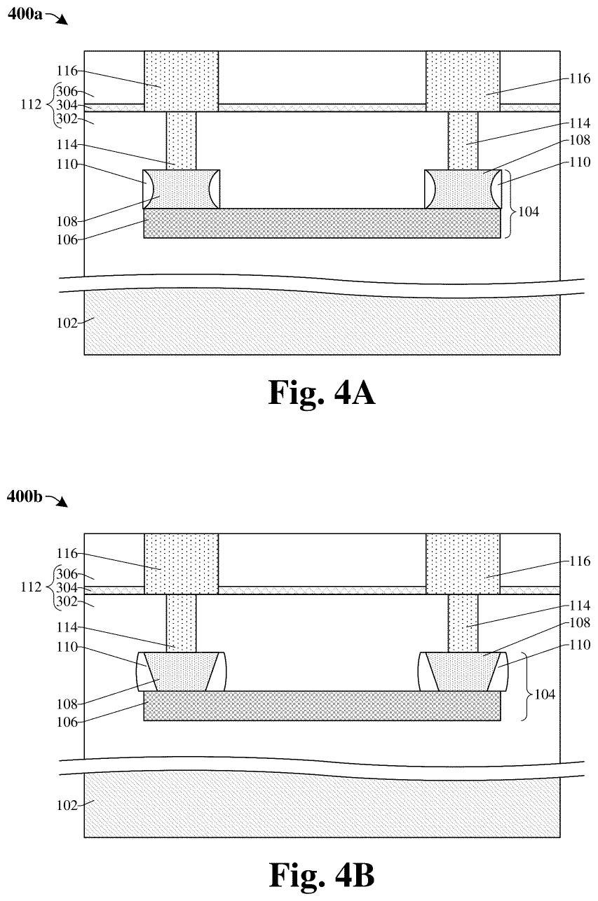

FIG. 4A illustrates a cross-sectional view 400a corresponding to some other embodiments of the integrated chip of FIG. 3A, in which the capping structures 108 respectively comprise curved opposing sidewalls. In some embodiments, the cavities 110 directly contact and conform to a shape of the curved opposing sidewalls of the capping structures 108. Further, heights of the cavities 110 may be equal to or less than heights of the capping structures 108. In various embodiments, the cavities 110 may be defined by one or more surfaces of the first dielectric layer 302, one or more surfaces of the capping structures 108, and one or more surfaces of the TFR layer 106.

FIG. 4B illustrates a cross-sectional view 400b corresponding to other embodiments of the integrated chip of FIG. 4A, in which the capping structures 108 respectively comprise slanted opposing sidewalls.

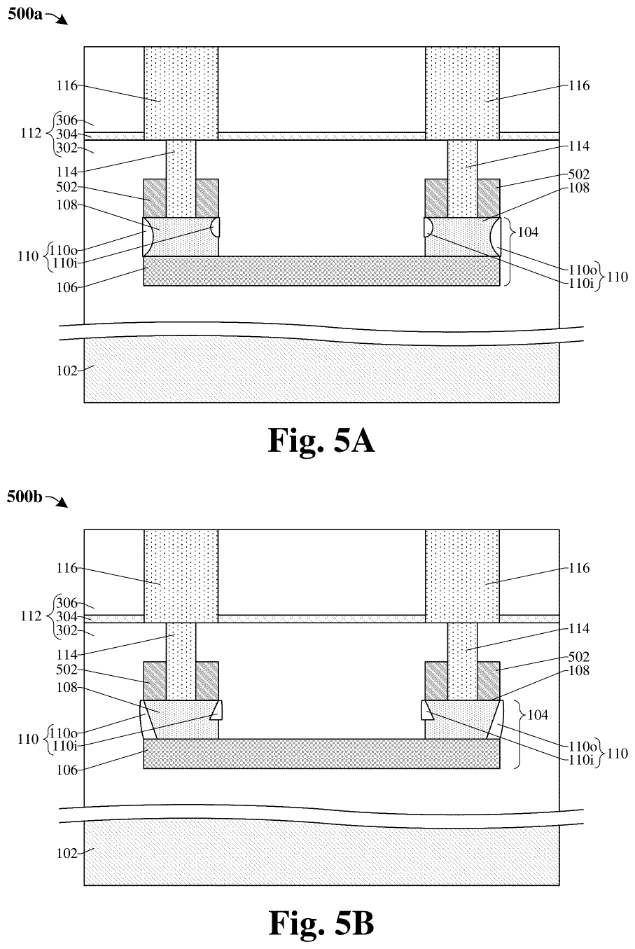

FIG. 5A illustrates a cross-sectional view 500a corresponding to some other embodiments of the integrated chip of FIG. 3A, in which the cavities 110 respectively comprise an inner cavity 110i and an outer cavity 110o. Further, a hard mask layer 502 is disposed on the capping structures 108. In some embodiments, the inner cavity 110i is disposed on a first side of a corresponding cavity and the outer cavity 110o is disposed on a second side of the corresponding cavity. Further, the inner cavity 110i and the outer cavity 110o are respectively adjacent to a corresponding curved sidewall segment of the corresponding cavity. In various embodiments, a height of the outer cavity 110o is greater than a height of the inner cavity 110i. In further embodiments, the outer cavity 110o is in fluid connection with the inner cavity 110i.

FIG. 5B illustrates a cross-sectional view 500b corresponding to other embodiments of the integrated chip of FIG. 5A, in which the capping structures 108 respectively comprise opposing sidewalls having at least one slanted sidewall segment. In various embodiments, the capping structures 108 respectively comprise a first slanted sidewall segment having a first height and a second slanted sidewall segment having a second height greater than the first height.

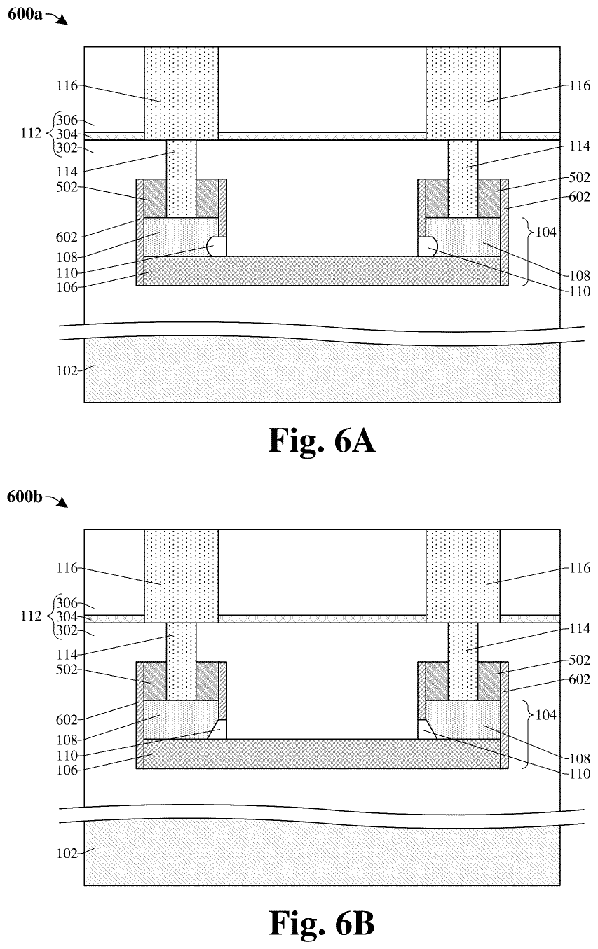

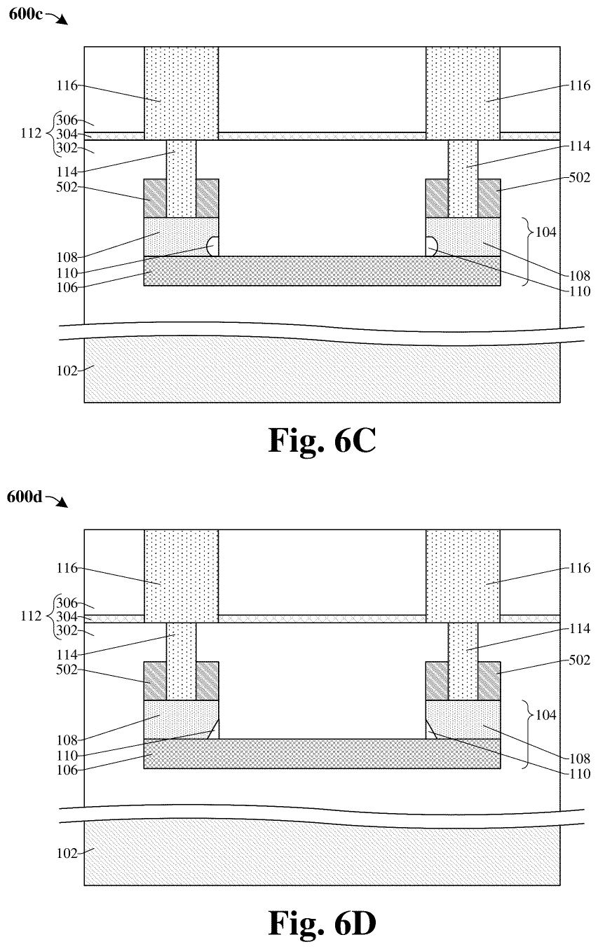

FIG. 6A illustrates a cross-sectional view 600a corresponding to some other embodiments of the integrated chip of FIG. 3A, in which a sidewall spacer structure 602 is disposed along opposing sidewalls of the capping structures 108. In various embodiments, the sidewall spacer structure 602 comprises silicon nitride, silicon carbide, or the like and/or has a thickness within a range of about 30 to 100 angstroms or some other suitable value. In yet further embodiments, the cavities 110 may be disposed along a corresponding inner sidewall of each capping structure 108. In some embodiments, the inner sidewalls of the capping structures 108 are curved. In various embodiments, the cavities 110 are defined by one or more surfaces of the first dielectric layer 302, one or more surfaces of the capping structures 108, one or more surfaces of the sidewall spacer structure 602, and/or one or more surfaces of the TFR layer 106.

FIG. 6B illustrates a cross-sectional view 600b corresponding to other embodiments of the integrated chip of FIG. 6A, in which the inner sidewalls of the capping structures 108 are slanted.

FIG. 6C illustrates a cross-sectional view 600c corresponding to other embodiments of the integrated chip of FIG. 6A, in which the sidewall spacer structure (602 of FIG. 6A) is omitted.

FIG. 6D illustrates a cross-sectional view 600d corresponding to other embodiments of the integrated chip of FIG. 6B, in which the sidewall spacer structure (602 of FIG. 6B) is omitted.

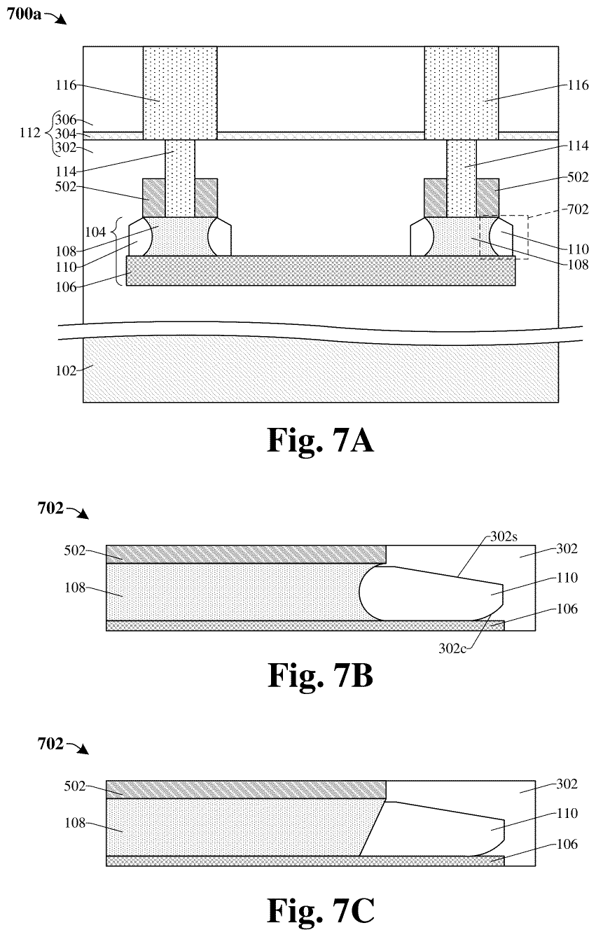

FIG. 7A illustrates a cross-sectional view 700a corresponding to some other embodiments of the integrated chip of FIG. 3A, in which the capping structures 108 are spaced away from a corresponding outer region of the TFR layer 106 towards a center of the TFR layer 106. In such embodiments, the capping structures 108 are spaced laterally between opposing outer sidewalls of the TFR layer 106.

FIG. 7B illustrates a cross-sectional view of some embodiments of an area 702 (e.g., see FIG. 7A) of the integrated chip of FIG. 7A. As shown in FIG. 7B, the cavity 110 continuously extends from a curved sidewall of the capping structure 108 to a top surface of the TFR layer 106. In some embodiments, the first dielectric layer 302 comprises a curved lower surface 302c that defines at least a portion of a bottom of the cavity 110 and the first dielectric layer 302 comprises a slanted upper surface 302s that defines at least a portion of a top of the cavity 110. In various embodiments, a width of the cavity 110 is greater than a height of the TFR layer 106.

FIG. 7C illustrates a cross-sectional view of some other embodiments of the area 702 (e.g., see FIG. 7A) of the integrated chip of FIG. 7A. As shown in FIG. 7C, in some embodiments, the capping structure 108 comprises a slanted sidewall and the cavity 110 continuously extends from the slanted sidewall of the capping structure 108 to the top surface of the TFR layer 106.

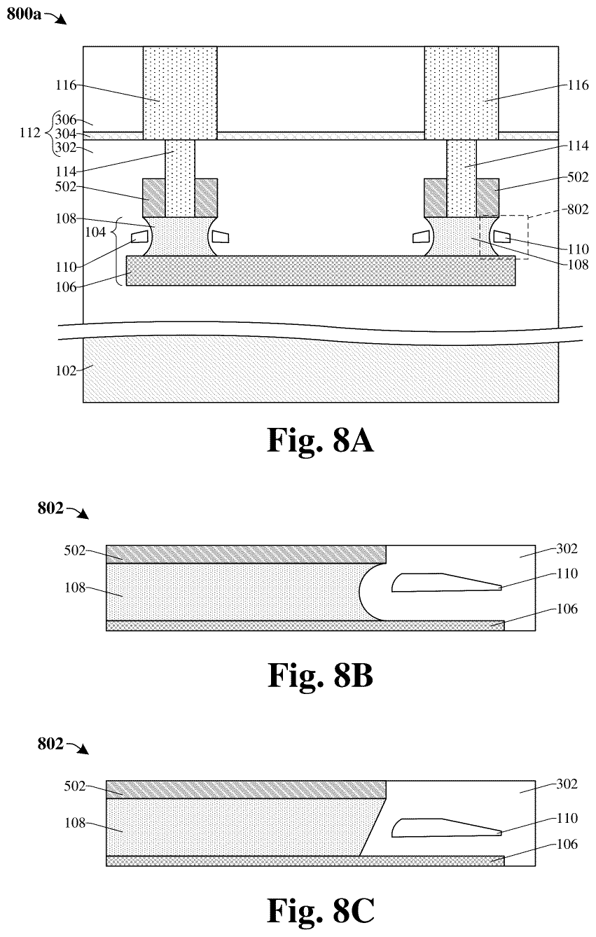

FIG. 8A illustrates a cross-sectional view 800a corresponding to some other embodiments of the integrated chip of FIG. 7A, in which heights of the cavities 110 are less than heights of the capping structures 108. In various embodiments, the cavities 110 are spaced from the capping structures 108 by the first dielectric layer 302. In further embodiment, the cavities 110 are spaced vertically between a bottom surface of the capping structures 108 and a top surface of the capping structure 108.

FIG. 8B illustrates a cross-sectional view of some embodiments of an area 802 (e.g., see FIG. 8A) of the integrated chip of FIG. 8A. As shown in FIG. 8B, the cavity 110 neighbors a curved sidewall of the capping structure 108. In various embodiments, the cavity 110 is laterally spaced from the curved sidewall of the capping structure 108 by a non-zero distance.

FIG. 8C illustrates a cross-sectional view of some other embodiments of the area 802 (e.g., see FIG. 8A) of the integrated chip of FIG. 8A. As shown in FIG. 8C, in some embodiments, the capping structure 108 comprises a slanted sidewall neighboring the cavity 110. In various embodiments, the cavity 110 is laterally spaced from the slanted sidewall of the capping structure 108 by a non-zero distance.

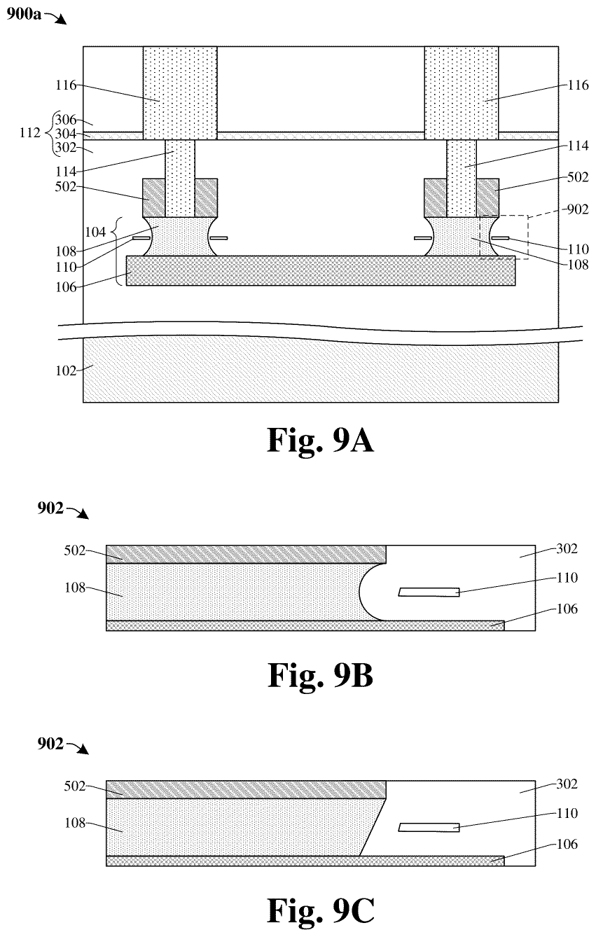

FIG. 9A illustrates a cross-sectional view 900a corresponding to some other embodiments of the integrated chip of FIG. 7A, in which heights of the cavities 110 are less than heights of the capping structures 108. In further embodiments, the heights of the cavities 110 are less than a height of the TFR layer 106. Further, the cavities 110 are spaced from the capping structures 108 by the first dielectric layer 302.

FIG. 9B illustrates a cross-sectional view of some embodiments of an area 902 (e.g., see FIG. 9A) of the integrated chip of FIG. 9A. As shown in FIG. 9B, the cavity 110 neighbors a curved sidewall of the capping structure 108.

FIG. 9C illustrates a cross-sectional view of some other embodiments of the area 902 (e.g., see FIG. 9A) of the integrated chip of FIG. 9A. As shown in FIG. 9C, in some embodiments, the capping structure 108 comprises a slanted sidewall neighboring the cavity 110.

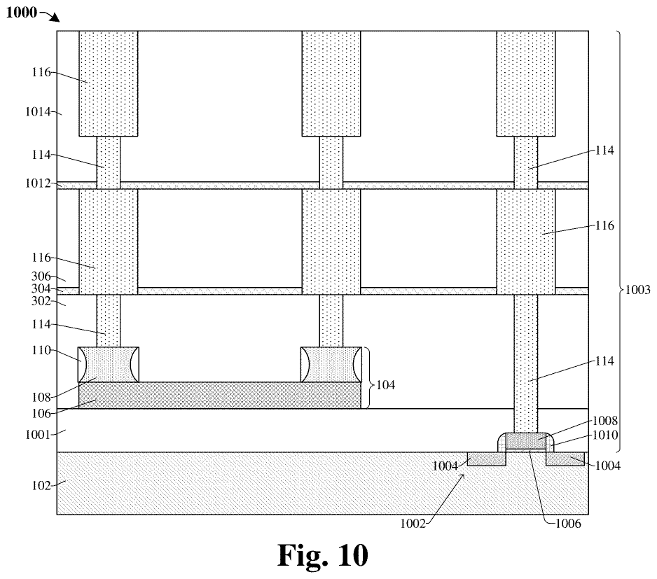

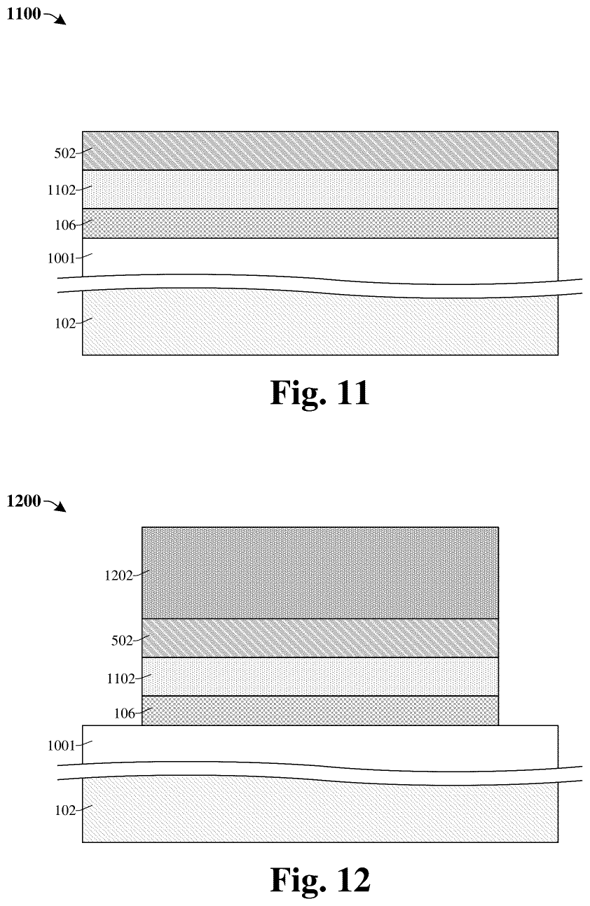

FIG. 10 illustrates a cross-sectional view 1000 of some embodiments of an integrated chip comprising a resistor structure 104 disposed within an interconnect structure 1003.

The interconnect structure 1003 overlies a semiconductor substrate 102. The semiconductor substrate 102 may, for example, be or comprise a semiconductor substrate material (e.g., silicon, silicon germanium, etc.), a bulk silicon substrate (e.g., bulk silicon), a semiconductor-on-insulator (SOI) substrate, one or more epitaxial layers, or another suitable substrate material. The interconnect structure 1003 comprises a plurality of dielectric layers 1001, 302-306, 1012, 1014, a plurality of conductive vias 114, and a plurality of conductive wires 116. The plurality of conductive vias 114 and the plurality of conductive wires 116 are disposed within the plurality of dielectric layers 1001, 302-306, 1012, 1014.

A semiconductor device 1002 is disposed within and/or on the semiconductor substrate 102. The semiconductor device 1002 may, for example, be a transistor and comprises source/drain regions 1004, a gate dielectric layer 1006, a gate electrode 1008, and a sidewall spacer structure 1010. The gate electrode 1008 overlies the gate dielectric layer 1006 and the source/drain regions 1004 are disposed within the semiconductor substrate 102 on opposing sides of the gate electrode 1008. Source/drain region(s) may refer to a source or a drain, individually or collectively dependent upon the context. The plurality of dielectric layers 1001, 302-306, 1012, 1014 includes a lower dielectric layer 1001, a first dielectric layer 302, a first etch stop layer 304, a second dielectric layer 306, a second etch stop layer 1012, and a third dielectric layer 1014. The lower dielectric layer 1001 overlies the semiconductor device 1002. In various embodiments, the resistor structure 104 is disposed on the lower dielectric layer 1001. The resistor structure 104 comprises a TFR layer 106 disposed along a top surface of the lower dielectric layer 1001 and capping structures 108 disposed on opposing sides of the TFR layer 106. Further, cavities 110 respectively neighbor a corresponding capping structure 108. By virtue of a CTE, size, and/or location of the cavities, stress applied to the TFR layer 106 by the capping structures 108 may be balanced and/or mitigated. As a result, an overall performance of the resistor structure 104 is improved.

FIGS. 11-16 illustrate cross-sectional views 1100-1600 of some embodiments of a method for forming an integrated chip including a resistor structure comprising cavities adjacent to capping structures. The integrated chip may, for example, correspond to the integrated chip of FIG. 4A. Although the cross-sectional views 1100-1600 shown in FIGS. 11-16 are described with reference to a method, it will be appreciated that the structures shown in FIGS. 11-16 are not limited to the method but rather may stand alone separate of the method. Furthermore, although FIGS. 11-16 are described as a series of acts, it will be appreciated that these acts are not limited in that the order of the acts can be altered in other embodiments, and the methods disclosed are also applicable to other structures. In other embodiments, some acts that are illustrated and/or described may be omitted in whole or in part.

As shown in cross-sectional view 1100 of FIG. 11, a lower dielectric layer 1001, a thin film resistor (TFR) layer 106, a capping layer 1102, and a hard mask layer 502 are formed over a semiconductor substrate 102. The lower dielectric layer 1001 may, for example, be formed by a chemical vapor deposition (CVD) process, a physical vapor deposition (PVD) process, an atomic layer deposition (ALD) process, or some other suitable deposition or growth process. The lower dielectric layer 1001 may, for example, be or comprise silicon dioxide, a low-k dielectric material (e.g., undoped silica glass (USG), carbon-doped silicon dioxide, etc.), some other suitable dielectric, or any combination of the foregoing. The TFR layer 106 may, for example, be formed by a CVD process, a PVD process, an ALD process, or some other suitable deposition or growth process. In some embodiments, the TFR layer 106 comprises a first material (e.g., silicon chromium, silicon chromium nickel, silicon chromium oxide, silicon chromium nitride, etc.) having a first CTE and/or is formed to a thickness within a range of about 5 to 200 angstroms, less than about 200 angstroms, or some other value.

The capping layer 1102 may, for example, be formed by a CVD process, a PVD process, an electroplating process, a sputtering process, or some other suitable deposition or growth process. In various embodiments, the capping layer 1102 comprises a second material (e.g., titanium nitride, titanium tungsten, tantalum nitride, tantalum tungsten, etc.) having a second CTE and/or is formed to a thickness within a range of about 50 to 1,000 angstroms or some other suitable value. In various embodiments, the second CTE is greater than the first CTE. The hard mask layer 502 may, for example, be formed by a CVD process, a PVD process, an ALD process, or some other suitable deposition or growth process. In some embodiments, the hard mask layer 502 is or comprises silicon dioxide, silicon oxynitride, silicon nitride, another dielectric material, or any combination of the foregoing and/or is formed to a thickness within a range of about 100 to 500 angstroms or some other suitable value. In various embodiments, the TFR layer 106, the capping layer 1102, and the hard mask layer 502 may be formed in separate processing chambers utilizing a cluster tool.

As shown in cross-sectional view 1200 of FIG. 12, a first patterning process is performed on the TFR layer 106, the capping layer 1102, and the hard mask layer 502. In some embodiments, the first patterning process includes: forming a first upper masking layer 1202 (e.g., comprising a photoresist or the like) on the hard mask layer 502 and performing an etching process (e.g., a dry etching process, a wet etching process, etc.) on the TFR layer 106, the capping layer 1102, and the hard mask layer 502 with the first upper masking layer 1202 in place. In some embodiments, the first upper masking layer 1202 is removed during or after the etching process (not shown).

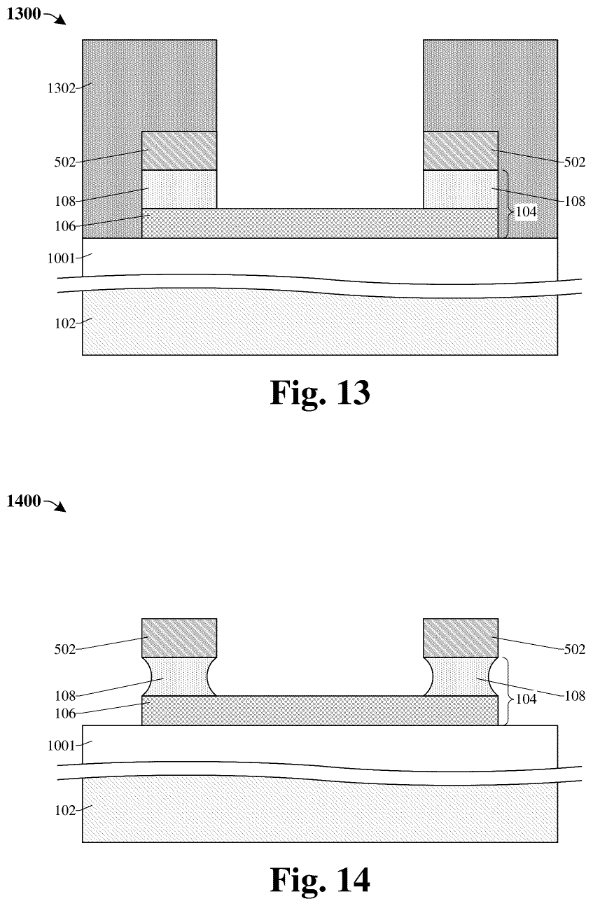

As shown in cross-sectional view 1300 of FIG. 13, a second patterning process is performed on the hard mask layer 502 and the capping layer (1102 of FIG. 12) thereby defining a plurality of capping structures 108 on the TFR layer 106 and defining a resistor structure 104. In some embodiments, the second pattering process includes: forming a second upper masking layer 1302 (e.g., comprising a photoresist or the like) on the hard mask layer 502 and performing an etching process (e.g., a dry etching process, a wet etching process, etc.) on the hard mask layer 502 and the capping layer (1102 of FIG. 12) with the second upper masking layer 1302 in place. In some embodiments, the second upper masking layer 1302 is removed during or after the etching process (not shown).

As shown in cross-sectional view 1400 of FIG. 14, an etching process is performed on the capping structures 108. In various embodiments, the etching process includes performing a wet etch process on the capping structures 108. In such embodiments, the etching process defines curved sidewalls in the capping structures 108 (e.g., as illustrated and/or described in FIG. 4A). In yet further embodiments, the etching process includes performing a plasma etch process with a voltage bias. In such embodiments, the etching process is performed such that the capping structures 108 comprise slanted sidewalls (e.g., as illustrated and/or described in FIG. 4B). In various embodiments, the etching process may include performing a wet etch process and a plasma etch process. The hard mask layer 502 may be removed by a removal process after the etching process (not shown). During the etching process the hard mask layer 502 has a first etching rate and the capping structures 108 have a second etching rate. In various embodiments, the second etching rate is greater than the first etching rate.

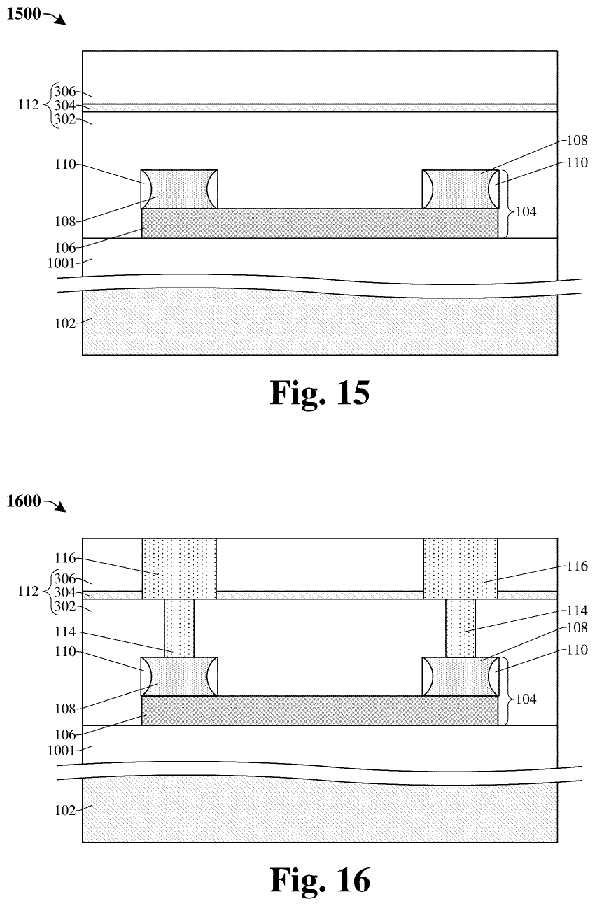

As shown in cross-sectional view 1500 of FIG. 15, a dielectric structure 112 is formed over the resistor structure 104, thereby sealing and/or forming cavities 110 abutting the capping structures 108. The dielectric structure 112 comprises a first dielectric layer 302, a second dielectric layer 306, and a first etch stop layer 304 disposed between the first and second dielectric layers 302, 306. The cavities 110 are defined at least in part by one or more surfaces of the first dielectric layer 302. In various embodiments, the cavities 110 may be formed in the first dielectric layer 302 by choosing a suitable formation process. A suitable formation process for forming the first dielectric layer 302 with the cavities 110 can be a non-conformal deposition process such as, for example, plasma enhanced chemical vapor deposition (PECVD). Non-conformal deposition processes creates cavities 110 in recessed areas such as around the sidewalls of the capping structures 108 (e.g., around curved sidewalls and/or slanted sidewalls of the capping structures 108). Other suitable formation processes for the first dielectric layer 302 may include, for example, metal organic chemical vapor deposition (MOCVD), remote plasma chemical vapor deposition (RPCVD), high density plasma chemical vapor deposition (HDPCVD), electron-cyclotron resonance (ECR) plasma-enhanced chemical vapor deposition (ECRCVD), hot wire chemical vapor deposition (HWCVD), or another suitable growth or deposition process. In further embodiments, the suitable formation process may include a CVD process with a suitable substrate bias to facilitate an anisotropic deposition of the first dielectric layer 302, thereby controlling a size of the cavities 110. In various embodiments, the cavities 110 are formed within the first dielectric layer 302 due to recessed areas of the capping structures 108 (e.g., by the sidewalls of the capping structures 108), the selected suitable formation process(es) for the first dielectric layer 302, and/or fill properties of the first dielectric layer 302.

Further, the first etch stop layer 304 is, for example, formed over the first dielectric layer 302 by a CVD process, a PVD process, an ALD process, or some other suitable growth or deposition process. The second dielectric layer 306 is formed over the first etch stop layer 304 by, for example, a CVD process, a PVD process, an ALD process, or some other suitable growth or deposition process. The first and second dielectric layers 302, 306 may, for example, be or comprise silicon dioxide, a low-k dielectric material such as undoped silica glass (USG) and/or carbon-doped silicon dioxide, some other suitable dielectric, or any combination of the foregoing. The first etch stop layer 304 may, for example, be or comprise silicon nitride, silicon carbide, or the like.

As shown in cross-sectional view 1600 of FIG. 16, a plurality of conductive vias 114 and a plurality of conductive wires 116 are formed over the resistor structure 104. In various embodiments, a process for forming the conductive vias and wires 114, 116 includes: forming a masking layer (not shown) over the dielectric structure 112; performing an etching process (e.g., a dry etch process, a wet etch process, etc.) on the dielectric structure 112 to form a plurality of openings in the dielectric structure 112; depositing (e.g., by CVD, PVD, sputtering, electroplating, etc.) a conductive material (e.g., aluminum, copper, titanium nitride, tungsten, another conductive material, or any combination of the foregoing) in the openings; and performing a planarization process (e.g., a chemical mechanical planarization (CMP) process) on the conductive material.

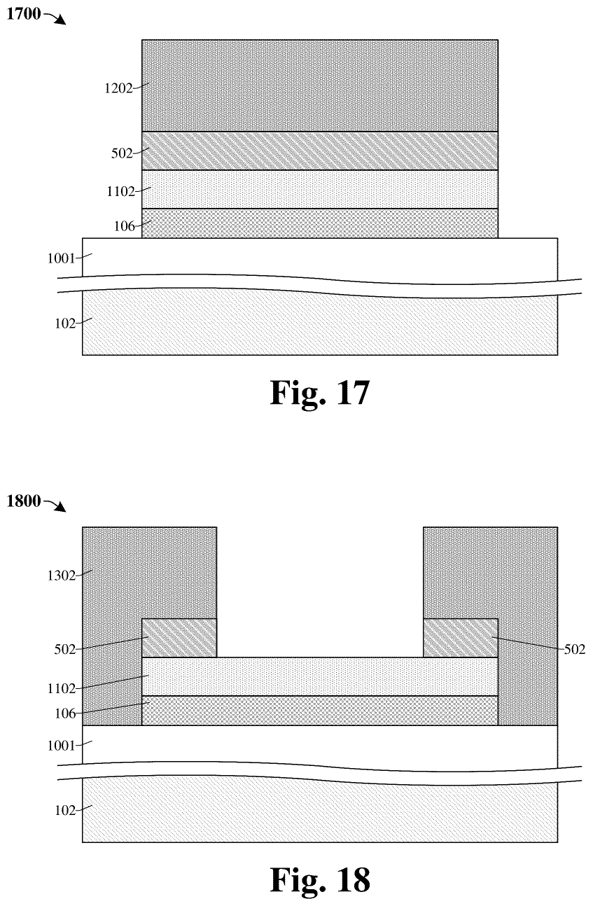

FIGS. 17-23 illustrate cross-sectional views 1700-2300 of some embodiments of a method for forming an integrated chip including a resistor structure comprising cavities adjacent to capping structures. The integrated chip may, for example, correspond to the integrated chip of FIG. 5A. Although the cross-sectional views 1700-2300 shown in FIGS. 17-23 are described with reference to a method, it will be appreciated that the structures shown in FIGS. 17-23 are not limited to the method but rather may stand alone separate of the method. Furthermore, although FIGS. 17-23 are described as a series of acts, it will be appreciated that these acts are not limited in that the order of the acts can be altered in other embodiments, and the methods disclosed are also applicable to other structures. In other embodiments, some acts that are illustrated and/or described may be omitted in whole or in part.

As shown in cross-sectional view 1700 of FIG. 17, a lower dielectric layer 1001, a TFR layer 106, a capping layer 1102, and a hard mask layer 502 are formed over a semiconductor substrate 102. Further, a first pattering process is performed on the TFR layer 106, the capping layer 1102, and the hard mask layer 502. The structure of FIG. 17 may, for example, be formed as illustrated and/or described in FIGS. 11 and 12.

As shown in cross-sectional view 1800 of FIG. 18, a second patterning process is performed on the hard mask layer 502. In some embodiments, the second patterning process includes: forming a second upper masking layer 1302 (e.g., comprising a photoresist or the like) on the hard mask layer 502 and performing an etching process (e.g., a dry etching process, a wet etching process, etc.) on the hard mask layer 502 with the second upper masking layer 1302 in place. In various embodiments, the second upper masking layer 1302 is removed during or after the etching process (not shown).

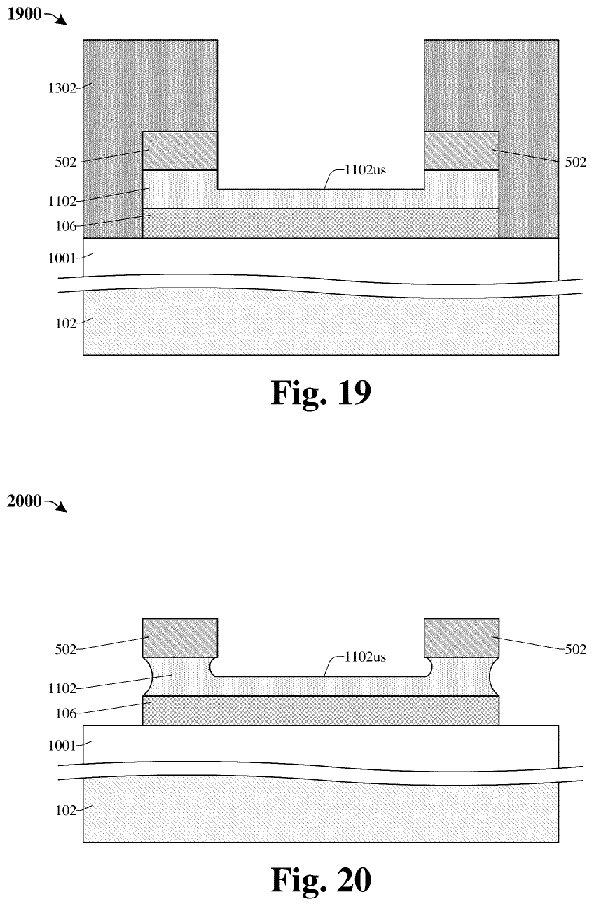

As shown in cross-sectional view 1900 of FIG. 19, a first etching process is performed on the capping layer 1102 to remove a portion of a middle region of the capping layer 1102, thereby defining an upper surface 1102us of the capping layer 1102. In some embodiments, the first etching process includes performing a plasma etch process, a reactive-ion etching process, some other suitable etch process, or any combination of the foregoing. In further embodiments, the first etching process is performed on the capping layer 1102 by virtue of the second upper masking layer 1302. In yet further embodiments, the second upper masking layer 1302 is removed during or after the first etching process (not shown).

As shown in cross-sectional view 2000 of FIG. 20, a second etching process is performed on the capping layer 1102. In various embodiments, the second etching process includes performing a wet etch process on the capping layer 1102. In such embodiments, the second etching process may define curved sidewalls in the capping layer 1102 (e.g., as illustrated and/or described in FIG. 5A). In further embodiments, the second etching process includes performing a plasma etch process, a plasma etch process with a voltage bias, or some other suitable dry etch process. In such embodiments, the second etching process may define slanted sidewalls in the capping layer 1102 (e.g., as illustrated and/or described in FIG. 5B). In yet further embodiments, the second etching process includes performing a wet etch process and a plasma etch process.

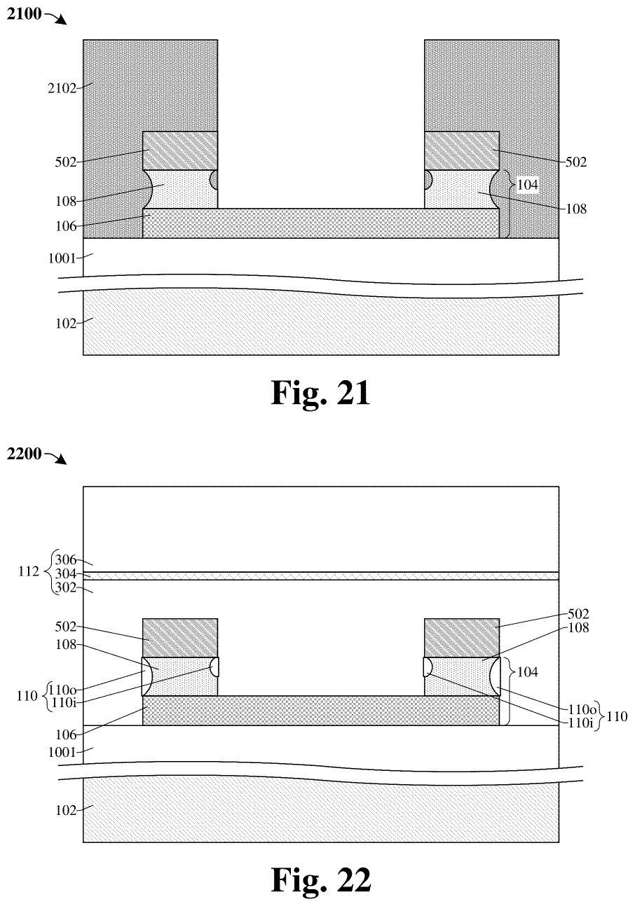

As shown in cross-sectional view 2100 of FIG. 21, a third patterning process is performed on the capping layer (1102 of FIG. 20), thereby defining a plurality of capping structures 108 and a resistor structure 104. In some embodiments, the third patterning process includes: forming a third upper masking layer 2102 (e.g., comprising a photoresist or the like) over the hard mask layer 502 and performing an etching process (e.g., a dry etching process, a wet etching process, etc.) on the capping layer (1102 of FIG. 20) with the third upper masking layer 2102 in place. In various embodiments, the third upper masking layer 2102 is removed during or after the etching process (not shown).

As shown in cross-sectional view 2200 of FIG. 22, a dielectric structure 112 is formed over the resistor structure 104, thereby sealing and/or forming cavities 110 abutting the capping structures 108. The dielectric structure 112 comprises a first dielectric layer 302, a second dielectric layer 306, and a first etch stop layer 304 disposed between the first and second dielectric layers 302, 306. The cavities 110 are defined at least in part by one or more surfaces of the first dielectric layer 302. In some embodiments, the cavities 110 respectively comprise an outer cavity 110o disposed on a first side of a corresponding capping structure 108 and an inner cavity 110i disposed on a second side of the corresponding capping structure 108. In further embodiments, the inner cavity 110i and the outer cavity 110o of each of the cavities 110 are in fluid communication with one another. In various embodiments, the cavities 110 may be formed in the first dielectric layer 302 by choosing a suitable formation process for the first dielectric layer 302. The suitable formation process may, for example, be or comprise PECVD, MOCVD, RPCVD, HDPCVD, ECRCVD, HWCVD, or another suitable growth or deposition process. In yet further embodiments, the dielectric structure 112 and/or the cavities 110 is/are formed as illustrated and/or described in FIG. 15.

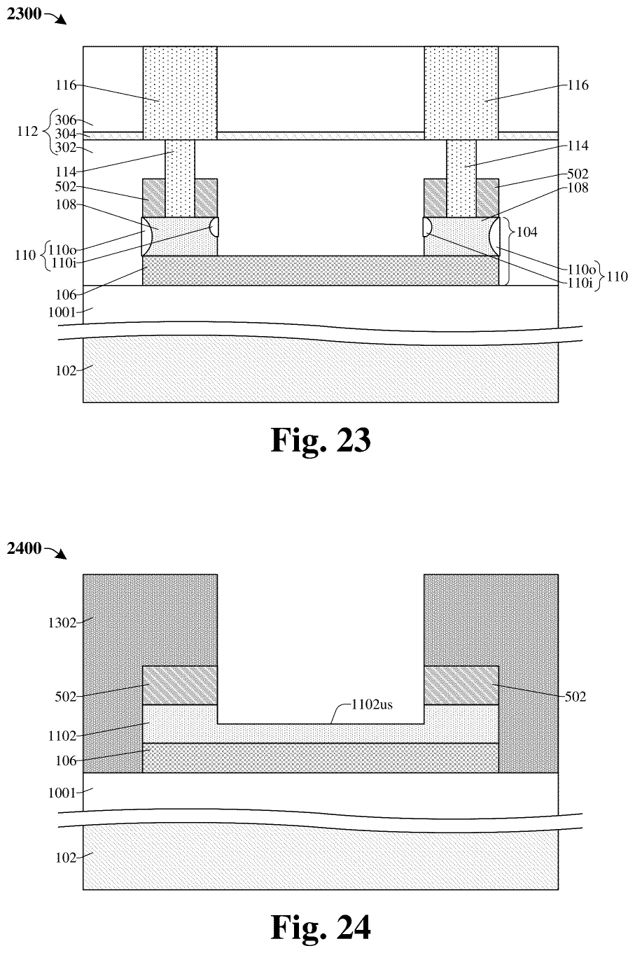

As shown in cross-sectional view 2300 of FIG. 23, a plurality of conductive vias 114 and a plurality of conductive wires 116 are formed over the resistor structure 104. In various embodiments, a process for forming the conductive vias and wires 114, 116 includes: forming a masking layer (not shown) over the dielectric structure 112; performing an etching process (e.g., a dry etch process, a wet etch process, etc.) on the dielectric structure 112 to form a plurality of openings in the dielectric structure 112 and/or the hard mask layer 502; depositing (e.g., by CVD, PVD, sputtering, electroplating, etc.) a conductive material (e.g., aluminum, copper, titanium nitride, tungsten, another conductive material, or any combination of the foregoing) in the openings; and performing a planarization process (e.g., a CMP process or the like) on the conductive material.

FIGS. 24-29 illustrate cross-sectional views 2400-2900 of some embodiments of a method for forming an integrated chip including a resistor structure comprising cavities adjacent to capping structures. The integrated chip may, for example, corresponding to the integrated chip of FIG. 6A. Although the cross-sectional views 2400-2900 shown in FIGS. 24-29 are described with reference to a method, it will be appreciated that the structures shown in FIGS. 24-29 are not limited to the method but rather may stand alone separate of the method. Furthermore, although FIGS. 24-29 are described as a series of acts, it will be appreciated that these acts are not limited in that the order of the acts can be altered in other embodiments, and the methods disclosed are also applicable to other structures. In other embodiments, some acts that are illustrated and/or described may be omitted in whole or in part.

As shown in cross-sectional view 2400 of FIG. 24, a lower dielectric layer 1001, a TFR layer 106, a capping layer 1102, and a hard mask layer 502 are formed over a semiconductor substrate 102. Further, one or more patterning processes is/are preformed on the TFR layer 106, the capping layer 1102, and/or the hard mask layer 502. The structure of FIG. 24 may, for example, be formed as illustrated and/or described in FIGS. 17-19.

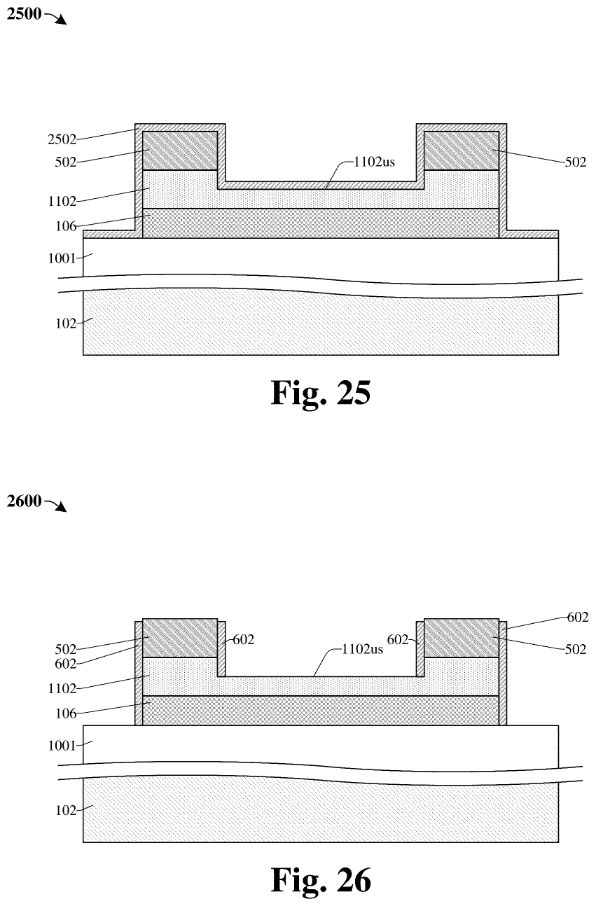

As shown in cross-sectional view 2500 of FIG. 25, a sidewall spacer layer 2502 is formed over the hard mask layer 502, the capping layer 1102, and the lower dielectric layer 1001. In some embodiments, the sidewall spacer layer 2502 is formed over the hard mask layer 502 the capping layer 1102, and the lower dielectric layer 1001 by a CVD process, a PVD process, an ALD process, or some other suitable formation or growth process. The sidewall spacer layer 2502 may, for example, be or comprise silicon nitride, silicon carbide, silicon oxynitride, some other suitable dielectric material, or any combination of the foregoing. In various embodiments, the sidewall spacer layer 2502 is formed to a thickness within a range of about 30 to 100 angstroms or some other suitable value.

A shown in cross-sectional view 2600 of 26, a first etching process is performed on the sidewall spacer layer (2502 of FIG. 25) to define and/or form a sidewall spacer structure 602 along sidewalls of the hard mask layer 502, sidewalls of the capping layer 1102, and sidewalls of the TFR layer 106. In various embodiments, the first etching process is configured to remove the sidewall spacer layer (2502 of FIG. 25) from horizontal surfaces such as the upper surface 1102us of the capping layer 1102, a top surface of the hard mask layer 502, and/or a top surface of the lower dielectric layer 1001. In various embodiments, the first etching process includes performing a dry etching process, a plasma etching process, a blanket etching process, another suitable etching process, or any combination of the foregoing.

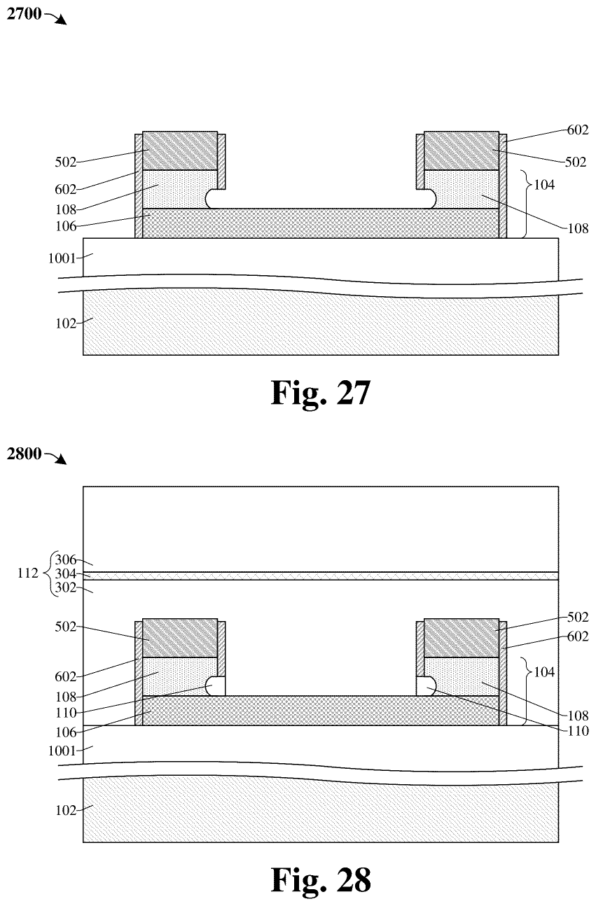

As shown in cross-sectional view 2700 of FIG. 27, a second etching process is performed on the capping layer (1102 of FIG. 26), thereby defining and/or forming capping structures 108 over the TFR layer 106. In some embodiments, the second etching process comprises performing a plasma etch process, a reactive-ion etch process, a wet etch process, some other suitable etch process, or any combination of the foregoing. In further embodiments, the second etching process includes performing a wet etch process on the capping layer 1102, such that the second etching process may define at least one curved inner sidewall in each of the capping structures 108 (e.g., as illustrated and/or described in FIG. 6A). In yet further embodiments, the second etching process includes performing a plasma etch process, a plasma etch process with a voltage bias, or some other suitable dry etch process, such that the second etching process may define at least one slanted sidewall in each of the capping structures 108 (e.g., as illustrated and/or described in FIG. 6B). In some embodiments, after the second etching process, a removal process is performed to remove the sidewall spacer structure 602 (not shown) (e.g., as illustrated and/or described in FIGS. 6C and/or 6D).

As shown in cross-sectional view 2800 of FIG. 28, a dielectric structure 112 is formed over the resistor structure 104, thereby sealing and/or forming cavities 110 abutting the capping structures 108. The dielectric structure 112 comprises a first dielectric layer 302, a second dielectric layer 306, and a first etch stop layer 304 disposed between the first and second dielectric layers 302, 306. The cavities 110 are defined at least in part by one or more surfaces of the first dielectric layer 302. In various embodiments, the cavities 110 are formed in the first dielectric layer 302 by choosing a suitable formation process for the first dielectric layer 302. The suitable formation process may, for example, be or comprise PECVD, MOCVD, RPCVD, HDPCVD, ECRCVD, HWCVD, or another suitable growth or deposition process. In yet further embodiments, the dielectric structure 112 and/or the cavities 110 is/are formed as illustrated and/or described in FIG. 15.

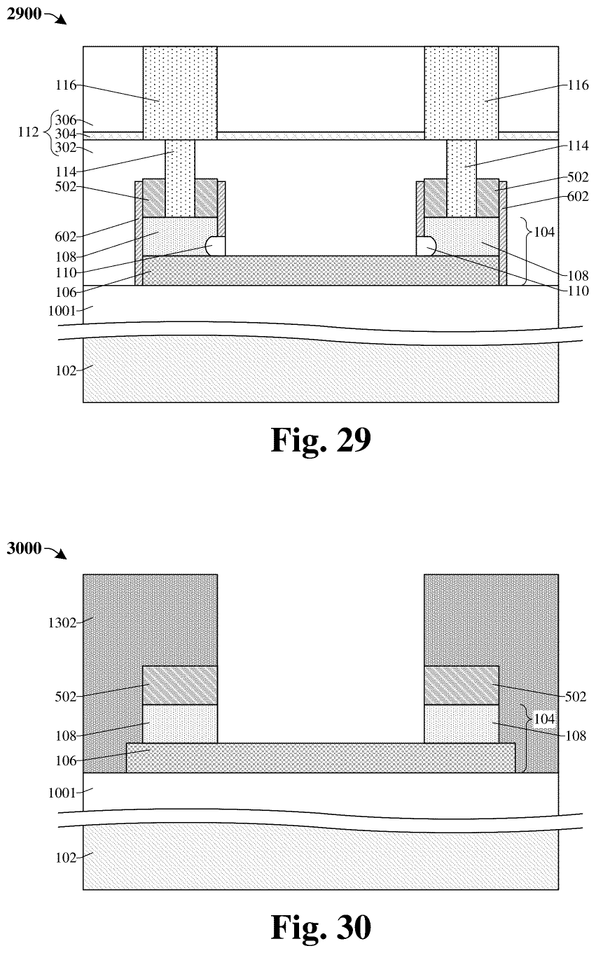

As shown in cross-sectional view 2900 of FIG. 29, a plurality of conductive vias 114 and a plurality of conductive wires 116 are formed over the resistor structure 104. In various embodiments, a process for forming the conductive vias and wires 114, 116 includes: forming a masking layer (not shown) over the dielectric structure 112; performing an etching process (e.g., a dry etch process, a wet etch process, etc.) on the dielectric structure 112 to form a plurality of openings in the dielectric structure 112 and/or the hard mask layer 502; depositing (e.g., by CVD, PVD, sputtering, electroplating, etc.) a conductive material (e.g., aluminum, copper, titanium nitride, tungsten, another conductive material, or any combination of the foregoing) in the openings; and performing a planarization process (e.g., a CMP process or the like) on the conductive material.

FIGS. 30-33 illustrate cross-sectional views 3000-3300 of some embodiments of a method for forming an integrated chip including a resistor structure comprising cavities adjacent to capping structures. The integrated chip may, for example, corresponding to the integrated chip of FIG. 7A. Although the cross-sectional views 3000-3300 shown in FIGS. 30-33 are described with reference to a method, it will be appreciated that the structures shown in FIGS. 30-33 are not limited to the method but rather may stand alone separate of the method. Furthermore, although FIGS. 30-33 are described as a series of acts, it will be appreciated that these acts are not limited in that the order of the acts can be altered in other embodiments, and the methods disclosed are also applicable to other structures. In other embodiments, some acts that are illustrated and/or described may be omitted in whole or in part.

As shown in cross-sectional view 3000 of FIG. 30, a lower dielectric layer 1001, a TFR layer 106, capping structures 108, and a hard mask layer 502 are formed over a semiconductor substrate 102. Further, one or more patterning processes is/are performed on the TFR layer 106, the capping structures 108, and/or the hard mask layer 502, thereby defining and/or forming a resistor structure 104 over the semiconductor substrate 102. The structure of FIG. 30 may, for example, be formed as illustrated and/or described in FIGS. 11-13.

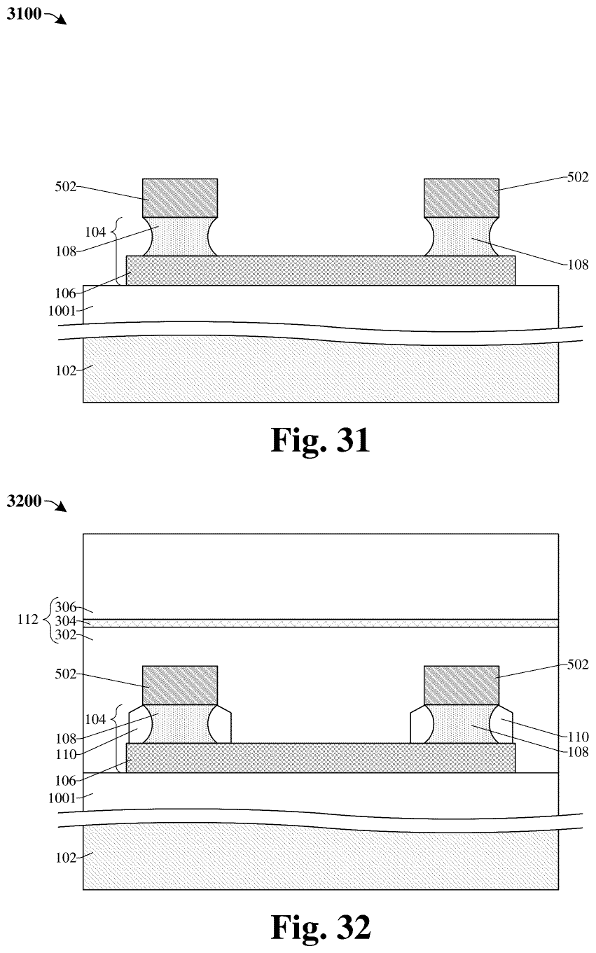

As shown in cross-sectional view 3100 of FIG. 31, an etching process is performed on the capping structures 108. In various embodiments, the etching process includes performing a wet etch process on the capping structures 108. In such embodiments, the etching process defines curved sidewalls in the capping structures 108. In yet further embodiments, the etching process includes performing a plasma etch process with a voltage bias, some other suitable dry etch process, or the like. In such embodiments, the etching process is performed such that the capping structures 108 comprise slanted sidewalls (not shown). In further embodiments, a size and/or shape of the sidewalls of the capping structures 108 may be controlled and/or defined based on an etching time of the etching process, a concentration of etchants used during the etching process (e.g., a concentration of wet etchants utilized during the etching process), a value of a voltage bias applied during a dry etch process, or the like.

As shown in cross-sectional view 3200 of FIG. 32, a dielectric structure 112 is formed over the resistor structure 104, thereby sealing and/or forming cavities 110 abutting the capping structures 108. The dielectric structure 112 comprises a first dielectric layer 302, a second dielectric layer 306, and a first etch stop layer 304 disposed between the first and second dielectric layers 302, 306. The cavities 110 are defined at least in part by one or more surfaces of the first dielectric layer 302. In various embodiments, the cavities 110 are formed in the first dielectric layer 302 by choosing a suitable formation process for the first dielectric layer 302. The suitable formation process may, for example, be or comprise PECVD, MOCVD, RPCVD, HDPCVD, ECRCVD, HWCVD, ALD, some other suitable growth or deposition process, or any combination of the foregoing. In yet further embodiments, the dielectric structure 112 and/or the cavities 110 is/are formed as illustrated and/or described in FIG. 15.

In yet further embodiments, size and/or shapes of the cavities 110 may be controlled by adjusting the formation process for the first dielectric layer 302. For example, the first dielectric layer 302 may be formed by a CVD process with a suitable substrate bias to set the size and/or shape of each of the cavities 110. In some embodiments, the first dielectric layer 302 may be formed by an ALD process and a CVD process to control sizes of the cavities 110. In various embodiments, sizes or the cavities 110 are determined or controlled at least in part by a shape of the sidewalls of the capping structures 108, wherein the shape of the sidewalls of the capping structures 108 may be controlled by an etching time, etchant solution concentration (e.g., wet etchant concentration), appropriate voltage bias, or the like during the etching process of FIG. 31.

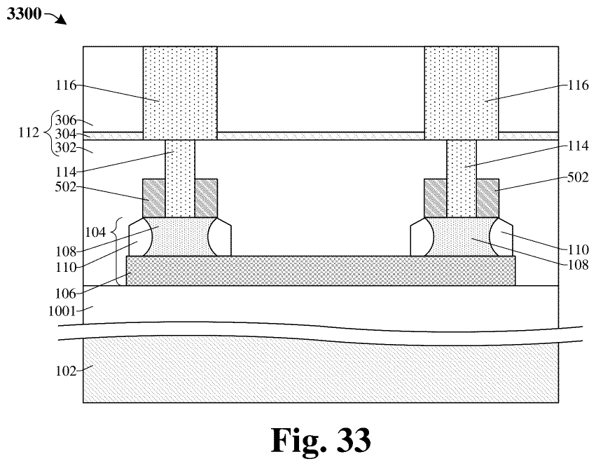

As shown in cross-sectional view 3300 of FIG. 33, a plurality of conductive vias 114 and a plurality of conductive wires 116 are formed over the resistor structure 104. In various embodiments, a process for forming the conductive vias and wires 114, 116 includes: forming a masking layer (not shown) over the dielectric structure 112; performing an etching process (e.g., a dry etch process, a wet etch process, etc.) on the dielectric structure 112 to form a plurality of openings in the dielectric structure 112 and/or the hard mask layer 502; depositing (e.g., by CVD, PVD, sputtering, electroplating, etc.) a conductive material (e.g., aluminum, copper, titanium nitride, tungsten, another conductive material, or any combination of the foregoing) in the openings; and performing a planarization process (e.g., a CMP process or the like) on the conductive material.

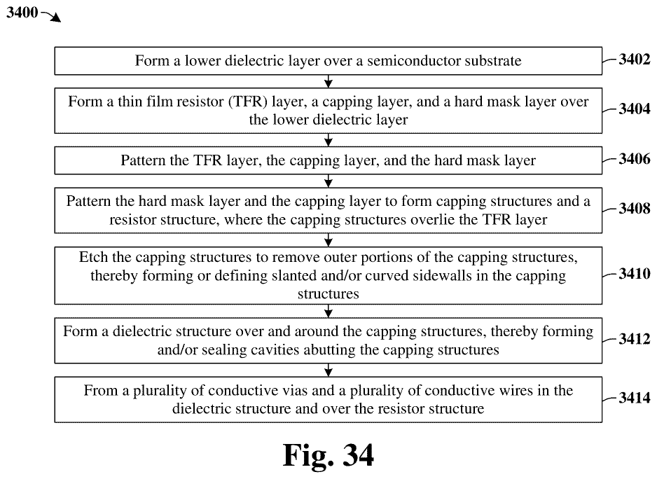

FIG. 34 illustrates a flowchart of some embodiments of a method 3400 for forming an integrated chip including a resistor structure comprising cavities adjacent to capping structures. Although the method 3400 is illustrated and/or described as a series of acts of events, it will be appreciated that the method is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At act 3402, a lower dielectric layer is formed over a semiconductor substrate. FIG. 11 illustrates cross-sectional view 1100 corresponding to some embodiments of act 3402.

At act 3404, a thin film resistor (TFR) layer, a capping layer, and a hard mask layer are formed over the lower dielectric layer. FIG. 11 illustrates cross-sectional view 1100 corresponding to some embodiments of act 3404.

At act 3406, the TFR layer, the capping layer, and the hard mask layer are patterned. FIG. 12 illustrates cross-sectional view 1200 corresponding to some embodiments of act 3406.

At act 3408, the hard mask layer and the capping layer are patterned to form capping structures and a resistor structure, where the capping structures overlie the TFR layer. FIG. 13 illustrates cross-sectional view 1300 corresponding to some embodiments of act 3408. FIGS. 18-21 illustrate cross-sectional views 1800-2100 corresponding to various embodiments of act 3408. FIGS. 24-27 illustrate cross-sectional views 2400-2700 corresponding to further embodiments of act 3408. FIG. 30 illustrates cross-sectional view 3000 corresponding to yet further embodiments of act 3408.

At act 3410, the capping structures are etched to remove outer portions of the capping structures, thereby forming or defining slanted and/or curved sidewalls in the capping structures. FIG. 14 illustrates cross-sectional view 1400 corresponding to some embodiments of act 3410. FIGS. 20 and 21 illustrate cross-sectional views 2000 and 2100 corresponding to various embodiments of act 3410. FIG. 27 illustrates cross-sectional view 2700 corresponding to further embodiments of act 3410. FIG. 31 illustrates cross-sectional view 3100 corresponding to yet further embodiments of act 3410.

At act 3412, a dielectric structure is formed over and around the capping structures, thereby forming and/or sealing cavities abutting the capping structures. FIG. 15 illustrates cross-sectional view 1500 corresponding to some embodiments of act 3412. FIG. 22 illustrates cross-sectional view 2200 corresponding to various embodiments of act 3412. FIG. 28 illustrates cross-sectional view 2800 corresponding to further embodiments of act 3412. FIG. 32 illustrates cross-sectional view 3200 corresponding to yet further embodiments of act 3412.

At act 3414, a plurality of conductive vias and a plurality of conductive wires are formed in the dielectric structure and over the resistor structure. FIG. 16 illustrates cross-sectional view 1600 corresponding to some embodiments of act 3414. FIG. 23 illustrates cross-sectional view 2300 corresponding to various embodiments of act 3414. FIG. 29 illustrates cross-sectional view 2900 corresponding to further embodiments of act 3414. FIG. 33 illustrates cross-sectional view 3300 corresponding to yet further embodiments of act 3414.

Accordingly, in some embodiments, the present disclosure relates to a resistor structure comprising a thin film resistor (TFR) layer, capping structures on the TFR layer, and cavities abutting the capping structures.

In some embodiments, the present application provides an integrated chip, including: a semiconductor substrate; a dielectric structure overlying the semiconductor substrate; a resistor structure disposed within the dielectric structure, wherein the resistor structure comprises a thin film resistor (TFR) layer and a first capping structure disposed on the TFR layer; and a first cavity disposed within the dielectric structure and abutting a first sidewall of the first capping structure.

In some embodiments, the present application provides an integrated chip, including: a semiconductor substrate; a dielectric structure overlying the semiconductor substrate; a resistor structure disposed within the dielectric structure, wherein the resistor structure comprises a thin film resistor (TFR) layer, a first capping structure, and a second capping structure, wherein the first and second capping structures are disposed on opposing sides of the TFR layer; a plurality of conductive vias disposed within the dielectric structure and overlying the first and second capping structures; a first air-gap disposed in the dielectric structure and adjacent to the first capping structure; and a second air-gap disposed in the dielectric structure adjacent to the second capping structure.

In some embodiments, the present application provides a method for forming an integrated chip, including: depositing a thin film resistor (TFR) layer over a semiconductor substrate; depositing a capping layer on the TFR layer; performing a first patterning process on the TFR layer and the capping layer to remove peripheral regions of the TFR layer and the capping layer; performing a second patterning process on the capping layer to form a first capping structure on the TFR layer; etching the first capping structure to remove an outer portion of the first capping structure; and forming a dielectric structure over and around the first capping structure such that at least one or more surfaces of the dielectric structure define a first cavity adjacent to the first capping structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated chip, comprising:
a semiconductor substrate;
a dielectric structure overlying the semiconductor substrate;
a resistor structure disposed within the dielectric structure, wherein the resistor structure comprises a thin film resistor (TFR) layer and a first capping structure disposed on the TFR layer; and
a first cavity disposed within the dielectric structure and abutting a first sidewall of the first capping structure.

2. The integrated chip of claim 1, wherein a first coefficient of thermal expansion (CTE) of the TFR layer is less than a second CTE of the first capping structure.

3. The integrated chip of claim 2, wherein a third CTE of the first cavity is greater than the second CTE.

4. The integrated chip of claim 1, wherein the first cavity laterally extends over an upper surface of the TFR layer.

5. The integrated chip of claim 1, wherein the resistor structure further comprises a second capping structure disposed on the TFR layer and laterally spaced from the first capping structure, wherein a second cavity is disposed within the dielectric structure and abuts a sidewall of the second capping structure.

6. The integrated chip of claim 1, wherein the first sidewall comprises a first curved segment, wherein a shape of the first cavity conforms to the first curved segment.

7. The integrated chip of claim 6, wherein the first capping structure comprises a second sidewall opposite the first sidewall, wherein the second sidewall comprises a second curved segment, wherein a second cavity is disposed within the dielectric structure and conforms to the second curved segment, wherein a height of the first cavity is greater than a height of the second cavity.

8. The integrated chip of claim 1, further comprising a first hard mask layer disposed on a top surface of the first capping structure, wherein a top of the first cavity is disposed below a top surface of the first hard mask layer.

9. An integrated chip, comprising:
a semiconductor substrate;
a dielectric structure overlying the semiconductor substrate;
a resistor structure disposed within the dielectric structure, wherein the resistor structure comprises a thin film resistor (TFR) layer, a first capping structure, and a second capping structure, wherein the first and second capping structures are disposed on opposing sides of the TFR layer;
a plurality of conductive vias disposed within the dielectric structure and overlying the first and second capping structures;
a first air-gap disposed in the dielectric structure and adjacent to the first capping structure; and
a second air-gap disposed in the dielectric structure adjacent to the second capping structure.

10. The integrated chip of claim 9, wherein the first and second capping structures comprise a conductive material.

11. The integrated chip of claim 9, wherein the first air-gap laterally wraps around an outer perimeter of the first capping structure.

12. The integrated chip of claim 9, further comprising:
a first sidewall spacer structure disposed along sidewalls of the first capping structure, wherein the first air-gap is disposed between a lower surface of a segment of the first sidewall spacer structure and a top surface of the TFR layer.

13. The integrated chip of claim 9, wherein coefficient of thermal expansions (CTEs) of the first and second capping structures are different from a CTE of the TFR layer, and wherein CTEs of the first and second air-gaps are greater than the CTEs of the first and second capping structures.

14. The integrated chip of claim 9, wherein the first air-gap is spaced laterally from an adjacent sidewall of the first capping structure by a non-zero distance, wherein the dielectric structure continuously laterally extends along the non-zero distance.

15. The integrated chip of claim 9, wherein bottoms of the first and second air-gaps are vertically above a top surface of the TFR layer.

16. An integrated chip, comprising:
a resistive layer overlying a semiconductor substrate;
a first conductive structure over the resistive layer and comprising a first sidewall laterally offset from a second sidewall;
a dielectric structure over the resistive layer and the first conductive structure; and
a first cavity in the dielectric structure, wherein the first cavity comprises a first segment adjacent to the first sidewall and a second segment adjacent to the second sidewall.

17. The integrated chip of claim 16, wherein a height of the first cavity is less than a thickness of the first conductive structure.

18. The integrated chip of claim 16, wherein a height of the first segment is different from a height of the second segment.

19. The integrated chip of claim 16, wherein the first segment is laterally offset from the second segment along a first direction, wherein the first and second segments are elongated in a second direction different from the first direction, wherein the first cavity further comprises a third segment extending along the first direction between the first and second segments.

20. The integrated chip of claim 16, further comprising:
a second conductive structure over the resistive layer and laterally offset from the first conductive structure; and
a second cavity in the dielectric structure, wherein the second cavity is arranged on opposing sides of the second conductive structure.
